(19) United States
(12) Patent Application Publication
(10) Pub. No.: US 2014/0273524 A1
(43) Pub. Date: Sep. 18, 2014

(54) Plasma Doping Of Silicon-Containing Films

(71) Applicants: Victor Nguyen, Novato, CA (US); Mihaela Balseanu, Sunnyvale, CA (US); Li-Qun Xia, Cupertino, CA (US); Ning Li, San Jose, CA (US); Martin A. Hilkene, Gilroy, CA (US); Matthew D. Scotney-Castle, Morgan Hill, CA (US)

(72) Inventors: Victor Nguyen, Novato, CA (US); Mihaela Balseanu, Sunnyvale, CA (US); Li-Qun Xia, Cupertino, CA (US); Ning Li, San Jose, CA (US); Martin A. Hilkene, Gilroy, CA (US); Matthew D. Scotney-Castle, Morgan Hill, CA (US)

(21) Appl. No.: 14/204,490

(22) Filed: Mar. 11, 2014

Related U.S. Application Data
(60) Provisional application No. 61/777,695, filed on Mar. 12, 2013.

(51) Int. Cl. H01L 21/02

(52) U.S. Cl. CPC H01L 21/02321; H01L 21/02323; H01L 21/02329
USPC 438/783

(57) ABSTRACT

Provided are methods for the deposition and doping of films comprising Si. Certain methods involve depositing a SiN, SiO, SiON, SiC or SiCN film and doping the Si-containing film with one or more of C, B, O, N and Ge by a plasma implantation process. Such doped Si-containing films may have improved properties such as reduced etch rate in acid-based clean solutions, reduced dielectric constant and/or improved dielectric strength.

### CROSS-REFERENCE TO RELATED APPLICATIONS

This application claims priority to U.S. Provisional Application No. 61/777,695, filed Mar. 12, 2013, the entire contents of which are herein incorporated by reference.

### TECHNICAL FIELD

The present invention relates generally to methods of depositing thin films. In particular, the invention relates to processes for the deposition and doping of Si-containing films.

### BACKGROUND

Deposition of thin films on a substrate surface is an important process in a variety of industries including semiconductor processing, diffusion barrier coatings and dielectrics for magnetic read/write heads. In the semiconductor industry, in particular, miniaturization requires atomic level control of thin film deposition to produce conformal coatings on high aspect ratio structures.

Conformal coverage with low pattern loading effect of dielectric films on high aspect ratio structures is a critical requirement as device nodes shrink down to below 45 nm. Furthermore, silicon nitride thin film is a commonly used dielectric throughout the semiconductor industry, but there is an increasing need for dielectric materials with lower dielectric constant (k) values and with lower etch rates in acid-based clean solutions.

Silicon carbide (oxy)nitride (SiCON/SiCN) films can exhibit some of these favorable qualities, but deposition of SiCON/SiCN films from furnace processes has several drawbacks. For example, these drawbacks include a high temperature requirement (≧550° C.), few capabilities to engineer film compositions and bonding structures. These properties are critical for wet etch resistance and electrical stability during thermal cycling for front-end of line (FEOL) applications. Films deposited via plasma enhanced chemical vapor deposition (PE-CVD) at lower temperature have poor step coverage due to directionality of the radicals' fluxes.

Accordingly, there is a need for improved methods for depositing various Si-containing films such as SiCON and SiCN.

### SUMMARY

One aspect of the invention relates to a method of depositing a film on a substrate, the method comprising depositing a Si-containing film on the substrate, wherein the Si-containing film is selected from the group consisting of SiN, SiO, SiON, SiC and SiCN, and doping the Si-containing film with one or more of dopants selected from C, B, O, N and Ge via a plasma implantation process to provide a doped film.

The Si-containing film may be deposited via any appropriate deposition process. In one or more embodiments, the Si-containing film is deposited via atomic layer deposition, plasma-enhanced atomic layer deposition, chemical vapor deposition, or spin-on dielectric deposition.

Certain combinations of Si-containing films and dopants may be advantageous. In some embodiments, such combinations include, but are not limited to: the Si-containing film is SiN, SiO or SiON and the dopant comprises C; the Si-containing film is SiN, SiC or SiCN and the dopant comprises B; the Si-containing film is SiN, SiC or SiCN and the dopant comprises O; the Si-containing film is SiC or SiCN and the dopant comprises N; the Si-containing film is SiN, SiC or SiCN and the dopant comprises Ge; the Si-containing film is SiN or SiO and the dopants comprise N and C; and the Si-containing film is SiN and the dopants comprise C and B.

According to one or more embodiments, the doped film may have a certain thickness, such as in the range from 2 to 30 nm.

Another aspect of the present invention pertain to a method of depositing a film on a substrate, the method comprising depositing a Si-containing film on the substrate, wherein the Si-containing film is selected from the group consisting of SiN, SiO, SiON, SiC and SiCN, and exposing the Si-containing film to a plasma comprising one or more dopant molecules comprising one or more of C, B, O, N and Ge.

Again, the Si-containing film may be deposited via any appropriate deposition process. In one or more embodiments, the Si-containing film is deposited via atomic layer deposition, plasma-enhanced atomic layer deposition, chemical vapor deposition, or spin-on dielectric deposition.

In one or more embodiments, the plasma comprises a saturated or unsaturated hydrocarbon.

In one or more embodiments, the plasma comprises diborane, hexamethyl borazine, a boron halide or a compound having the formula BHₓR₃₋ₓ, wherein each R is a C₁-C₆ alkyl group and x is 0, 1 or 2.

In one or more embodiments, the plasma comprises an alkyl amine.

In one or more embodiments, the plasma comprises germane or a germanium halide.

Yes another aspect of the present invention pertains to a method of depositing a C-doped SiN or SiON film on a substrate, the method comprising depositing SiN or SiON film on the substrate via atomic layer deposition or plasma-enhanced atomic layer deposition, and doping the SiN or SiON film with C via a plasma implantation process to provide a doped film.

In one or more embodiments of this aspect, doping the SiN or SiON film with C comprises exposing the SiN or SiON film to a plasma comprising a saturated or unsaturated hydrocarbon.

One or more embodiments provide that the doped film has a relative carbon content in the range from 0.05 to 10 a.u. In some embodiments, the doped film has a relative carbon content in the range from 0.1 to 1.0 a.u.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A and 1B show transmission electron microscope (TEM) images of a conformal nitride spacer on polysilicon structures in a dense 5:1 aspect ratio and on an open bare silicon substrate, respectively;

FIGS. 2A and 2B show TEM images of conformal SiCN spacers on polysilicon structures as-deposited and after clean in hydrofluoric (HF)-based solution, respectively;

FIG. 3 shows a graph of the dielectric constant of SiN films with various levels of C doping; and

FIG. 4 shows a graph of the breakdown voltage of SiN films with various levels of C doping.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways. It is also to be understood that the complexes and ligands of the present invention may be illustrated herein using structural formulas which have a particular stereochemistry. These illustrations are intended as examples only and are not to be construed as limiting the disclosed structure to any particular stereochemistry. Rather, the illustrated structures are intended to encompass all such complexes and ligands having the indicated chemical formula.

Provided are methods of depositing and doping Si-containing films that can be used to improve various properties of the films. For example, in some embodiments, a SiN, SiO or SiON film may be doped with C to reduce the wet etch rate (WER), a SiN, SiC or SiCN film may be doped with B or O to reduce the dielectric constant, or a SiC or SiCN film may be doped with N to improve the dielectric strength. Other combinations of dopant(s) and Si-containing films may provide enhancement of these or other properties. In some embodiments, the processes described herein may be used deposit low pattern loading, conformal films as spacer and etch stop layers in memory and logic process flow. If atomic layer deposition (ALD) is used to deposit the films, the processing temperature of well below 550° C. can be suitable for high-k dielectric materials. Another potential benefit of the processes described herein is the capability of tailoring conformal films to desired composition and properties. The films' dopant content can be tuned by plasma implantation.

Accordingly, one aspect of the invention relates to method of depositing a film. The method comprises depositing a Si-containing film such as SiN, SiO, SiON, SiC or SiCN on a substrate, then doping the Si-containing film with one or more of C, B, O, N and Ge. According to one or more embodiments, the doping is provided by a plasma implantation process.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present invention any of the film processing steps disclosed may also be performed on an underlayer formed on the substrate as disclosed in more detail below, and the term “substrate surface” is intended to include such underlayer as the context indicates.

In some embodiments, the substrate surface includes a layer that allows a reaction between the substrate surface and precursors used to deposit the Si-containing film. Examples include layers that contain reactive —OH or —NH moieties or handles.

The Si-containing film can be deposited using a variety of deposition processes. In one or more embodiments, the Si-containing film is deposited by atomic layer deposition (ALD), plasma-enhanced atomic layer deposition (PEALD), chemical vapor deposition (CVD), or spin-on dielectric (SOD) deposition. In some embodiments, ALD or PEALD is used so that there is precise control of the thickness of the Si-containing layer.

In an exemplary ALD process, a substrate is exposed to a first precursor such as a silicon precursor that reacts with the substrate surface to provide a monolayer of precursor on all structural surfaces. Silicon precursors include, but are not limited to, halogenated silane, amino-halogenated-silane, or carbo-halogenated-silane precursors that have halogen-terminated bonds. Examples of such halogenated precursors include hexachlorodisilane (HCDS), dichlorosilane (DCS), and bis(trischlorosilyl) methane (BTCSM). In some embodiments, the reaction is self-limiting because the layer has halogen-terminated bonds, thus providing excellent step coverage.

The substrate surface is then exposed to a co-reactant to form the Si-containing film. For example, if the film is SiN or SiCN, the substrate can then be exposed to reducing agents such as NH₃, CH₄, H₂, and N₂ or their plasma-generated radicals. Reactions of the film with these gases, occurring under pressure or plasma-assisted, result in the removal of halogen atoms cross-linking to form the Si—N—Si network. Other co-reactants for depositing other Si-containing films will be apparent to those skilled in the art. For example, H₂O, H₂O₂, O₂ or O₃ may be used as co-precursors for SiO or SiON film deposition.

The precursors may be flowed and/or exposed to the substrate surface either sequentially or substantially simultaneously. In embodiments where the substrate is exposed to the precursors sequentially, the process may be repeated up until a desired film thickness has been achieved. As used herein, “substantially simultaneously” refers to either co-flow or where there is merely overlap between exposures of the precursors. In one or more embodiments, a catalyst may be added with any one or more of the reactants.

The reaction conditions for the ALD reaction will be selected based on the properties of the film precursors, substrate surface, and the catalyst, if any. The deposition may be carried out at atmospheric pressure, but may also be carried out at reduced pressure. The vapor pressure of the catalyst should be low enough to be practical in such applications. The substrate temperature should be low enough to keep the bonds of the substrate surface intact and to prevent thermal decomposition of gaseous reactants. However, the substrate temperature should also be high enough to keep the film precursors in the gaseous phase and to provide sufficient energy for surface reactions. The specific temperature depends on the specific substrate, film precursors, and catalyst used and pressure. The properties of the specific substrate, film precursors, and catalyst may be evaluated using methods known in the art, allowing selection of appropriate temperature and pressure for the reaction.

In one or more embodiments, the deposition is carried out at a temperature less than about 550, 500, 450, 400, 350, 300, 250, 200, 150, 125, or 100° C. In some embodiments, the deposition is carried out at a temperature in the range of about 20 to about 500° C., about 100 to about 450° C. or about 300 to about 400° C.

In specific embodiments, the co-reactant may involve plasma excitation. In other embodiments involving the use of plasma, during the plasma step the reagents are generally ionized during the process, though this might occur only upstream of the deposition chamber such that ions or other energetic or light emitting species are not in direct contact with the depositing film, this configuration often termed a remote plasma. Thus, in this type of PEALD process, the plasma is generated external from the processing chamber, such as by a remote plasma generator system. During PEALD processes, a plasma field may be generated from a microwave (MW) frequency generator or a radio frequency (RF) generator. Although plasmas may be used during the ALD processes disclosed herein, it should be noted that plasmas are not required. Indeed, other embodiments relate to ALD under very mild conditions without plasma excitation.

After deposition of the Si-containing film, the film is doped with one or more desired dopants via a plasma implantation process. Such dopants can include C, B, O, N and Ge. The plasma doping process described herein may be used to control the amount of doping to tune various properties of the Si-containing film. By modulating plasma power, implant energy, and implant dosage, one can control how much dopant is incorporated to the original Si-containing film.

The dopants may be implanted into the Si-containing film by simultaneously exposing the film to a plasma environment and a dopant source. Examples of suitable dopant sources for carbon doping include saturated or unsaturated hydrocarbons, including aromatic hydrocarbons. Specific examples include methane (CH₄), ethane (C₂H₆) and benzene (C₆H₆). Examples of suitable dopant sources for boron doping include diborane, boron halides such as BCl₃ or substituted boron compounds having the formula BHₓR₃₋ₓ, wherein each R is a C₁-C₆ alkyl group and x is 0, 1 or 2. Specific examples of substituted boron compounds include trimethyl boron and triethyl boron. Examples of suitable dopant sources for carbon and nitrogen doping include alkyl amines such as dimethyl amine (DMA). An example of a suitable dopant source for boron, nitrogen and carbon doping is hexamethyl borazine. Examples of suitable dopant sources for germanium doping include germane (GeH₄) or a germanium halide such as germanium chloride (GeCl₄).

Suitable doping chambers include a plasma ion immersion implantation reactor, including but not limited to, the CONFORMA™ reactor commercially available from Applied Materials, Inc., of Santa Clara, Calif.

When doping the Si-containing film, the entire surface of the substrate may be doped or if select regions of the film are to be doped, a patterned mask layer, such as a patterned photoresist layer, may be deposited atop the film to protect regions of the film that are not to be doped.

For example, the dopant region may be formed by providing a first process gas comprising one or more precursor gases. The one or more precursor gases comprise the elements to be implanted, for example, any of the dopant elements described above. The first process gas may be provided in a suitable flow rate, for example from about 0.5 to about 600 sccm. In some embodiments, the first process gas may further comprise a carrier gas, for example such as an inert gas including but not limited to argon, helium, nitrogen, or the like. Embodiments where a carrier gas is provided, the carrier gas may comprise up to about 90 percent of the first process gas, or between about 1 to about 99 percent of the first process gas. The relative amount of dopant source gas in the carrier gas may be used to dilute or reduce the doping of the Si-containing film.

A plasma may be generated from the first process gas to implant the one or more dopants into the substrate to form the dopant region, or to deposit the one or more dopants atop the substrate to form the dopant region. The plasma may be formed by applying a source power at a suitable frequency.

The substrate may be biased during implantation and/or deposition to control the flux of ions towards the substrate, and, in some embodiments, to control the depth of ion penetration into the Si-containing film. For example, in some embodiments, up to about 10 to 11,000 watts of a substrate bias power at a frequency of between about 350 kHz to about 60 MHz, or about 2 MHz may be provided. During implantation and/or deposition, the source RF power can be about 100 to 4000 watts with a frequency between about 350 kHz to about 60 MHz, or about 13.5 MHz. The plasma process time may range from about 1 to about 120 seconds.

The plasma may be formed in a low pressure process, thereby reducing the likelihood of contamination induced defects in the substrate and/or amorphization of any underlying layer, such as a silicon-containing layer. For example, in some embodiments, the ion implantation may be performed at a pressure of between about 1 to about 500 mTorr. Moreover, ion bombardment-induced defects that may occur even at such pressure levels may be further limited or prevented by using a remote plasma source or by pulsing the plasma source power.

When the carbon and boron precursors are flowing and the RF source is enabled, unwanted C, B and BN films may deposit on the substrate. By optimizing the source power, pressure and precursor introduction time/flow and implant dose rate the unwanted deposition can be minimized. One example of deposition control can be introducing C and B precursors only at the final implant pressure (such as 5 to 25 mT for C and B), which can reduce deposition, instead of introducing C and B precursors at pressures used during the RF source strike (such as 25 to 100 mT) that will increase deposition. Another example of deposition control is to introduce the C and B precursors as close to the wafer bias on implant step as possible because the deposition rate is reduced during implant (RF source on+wafer bias on) and worse when RF source is on (wafer bias off+RF source on). This may be accomplished by turning the depositing dopant gas on 1 to 2 seconds before wafer bias is turned on. In some embodiments, the depositing dopant gas is turned on for no more than 5 seconds before the wafer bias is turned on. Yet another example of deposition control is to introduce the B and C precursors at low source powers (such as less than 400 W) because deposition rate increases at elevated source RF powers.

The doped Si-containing film may be a conformal film of any desired thickness. The film thickness of the doped film may be controlled by depositing a Si-containing film of the desired thickness, then doping the Si-containing film. In various embodiments, the thickness of the doped Si-containing films is in the range from 2 to 30 nm, such as from 2 to 10 nm. Exemplary film thicknesses may be less than or equal to the following values: 30, 25, 20, 15, 10, 9, 8, 7, 6, 5, 4, 3 or 2 nm.

As explained above, the plasma implantation process described herein may be used to control the amount of dopant incorporated in the Si-containing film. In some embodiments, the relative dopant content is in the range from 0.01 to 20 a.u. For example, the relative dopant content may be from 0.05 to 10 a.u., such as in the range from 0.1 to 5 a.u. or 0.1 to 2 a.u. The amount of doping may be adjusted according to the type of dopant(s) and Si-containing film, as well as the particular application of the doped film.

According to one or more embodiments, the substrate is subjected to processing prior to and/or after forming the doped Si-containing film. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus are disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

In atomic layer deposition type chambers, the substrate can be exposed to the first and second precursors either spatially or temporally separated processes. Temporal ALD is a traditional process in which the first precursor flows into the chamber to react with the surface. The first precursor is purged from the chamber before the second precursor is flown. In spatial ALD, both the first and second precursors are simultaneously flowed to the chamber but are separated spatially so that there is a region between the flows that prevents mixing of the precursors. In spatial ALD, the substrate must be moved relative to the gas distribution plate, or vice-versa.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

### EXAMPLES

### Example 1

### Deposition of Silicon Nitride

A conformal SiN film was deposited on a 5:1 aspect structure with a gap of 50 nm by ALD. The Si-containing precursor dichlorosilane (DCS) was flowed at 100 sccm and the reducing agent ammonia was flowed at 1000 sccm. Film deposition took place at a substrate temperature of 400° C. with a chamber pressure of 6 Torr. The carrier gas flow was 5000 sccm. Each monolayer of SiN was exposed to a 10 second pulse of plasma at 100 W and 13.6 MHz. A transmission electron microscope (TEM) image of the resulting SiN film is shown in FIG. 1A.

A SiN film was also deposited on an open bare silicon substrate in the same chamber under the same deposition conditions. A TEM of the blanket deposition is shown in FIG. 1B.

As can be seen from FIGS. 1A and 1B, the SiN film was highly conformal. The conformality of a film is measured by thickness on the sidewall and at gap's bottom compared to the top in the dense area. The pattern loading effect (PLE) is the difference in thicknesses on blanket and on structure. In FIG. 1A, the sidewall/top and bottom/top thickness ratio was measured to be 95%. The PLE between FIGS. 1A and 1B was 3%.

### Example 2

### Carbon Doping of Silicon Nitride

A SiN film was deposited on polysilicon structures by the same deposition process as Example 1. After deposition, the SiN film was doped with C via a plasma implantation process. The plasma comprised 70 sccm CH₄ in 100 sccm Ar. The temperature in the plasma implant chamber was below 400° C. and the pressure was 7 mTorr. The source plasma power was 400 W and the bias power was 1000 W. The implant energy was 3 KeV and the process time was 6 seconds. The resulting SiCN film had a relative carbon content of 0.3 a.u. FIG. 2A shows a TEM image of the resulting SiCN film. As can be seen, the SiCN film is highly conformal.

The wet etch resistance of this SiCN film was tested by hydrofluoric (HF) in peroxide solution clean. The SiCN film after HF clean had a preserved sidewall, as shown in the TEM image in FIG. 2B. This is an indication of good carbon incorporation to the structure's sidewall. This same effect is almost impossible to achieve with direct plasma treatment due to directionality of the ion and radical fluxes.

The dielectric constant (k) and breakdown voltage (V_{bd}) were measured for SiCN films having varying degrees of carbon doping. SiN with no carbon doping has a dielectric constant of 6.5, whereas carbon incorporation lowered the k value. A graph of the relationship between relative carbon content and dielectric constant for SiCN films is shown in FIG. 3.

However, increased carbon content also decreased the breakdown voltage of the film. A graph of the relationship between relative carbon content and breakdown voltage for SiCN films is shown in FIG. 4.

A comparison of FIGS. 3 and 4 shows that a small dosage of carbon doping can improve the k while preserving the ideal breakdown voltage of silicon nitride. Relative carbon contents below 1.0 a.u. had favorable k values and breakdown voltages.

Accordingly, carbon-doped SiN and SiON films are good candidates for spacer and etch-stop layer applications due to their lower dielectric constant k. Lower k improves RC capacitor delay, hence device performance. In addition, with carbon addition, the film is more resistance to hydrofluoric acid in peroxide (HF) and buffer oxide etch (BOE) wet clean. Therefore, thinner film is needed to have same barrier effect for the spacer, which is a critical requirement as devices move to smaller nodes. The main drawback for SiCN/SiCON films is lower breakdown voltage due to the semiconductor nature of the Si—C bond. The film is less stable under thermal cycling, such as 1050° C. rapid-thermal anneal (RTP) in FEOL process flow. However, low relative carbon contents in SiCN and SiCON films can provide a good balance of lower k values without resulting in breakdown voltages that are too low.

What is claimed is:

1. A method of depositing a film on a substrate, the method comprising:
depositing a Si-containing film on the substrate, wherein the Si-containing film is selected from the group consisting of SiN, SiO, SiON, SiC and SiCN; and
doping the Si-containing film with one or more of dopants selected from C, B, O, N and Ge via a plasma implantation process to provide a doped film.

2. The method of claim 1, wherein the Si-containing film is deposited via atomic layer deposition, plasma-enhanced atomic layer deposition, chemical vapor deposition, or spin-on dielectric deposition.

3. The method of claim 1, wherein the Si-containing film is SiN, SiO or SiON and the dopant comprises C.

4. The method of claim 1, wherein the Si-containing film is SiN, SiC or SiCN and the dopant comprises B.

5. The method of claim 1, wherein the Si-containing film is SiN, SiC or SiCN and the dopant comprises O.

6. The method of claim 1, wherein the Si-containing film is SiC or SiCN and the dopant comprises N.

7. The method of claim 1, wherein the Si-containing film is SiN, SiC or SiCN and the dopant comprises Ge.

8. The method of claim 1, wherein the Si-containing film is SiN or SiO and the dopants comprise N and C.

9. The method of claim 1, wherein the Si-containing film is SiN and the dopants comprise C and B.

10. The method of claim 1, wherein the doped film has a thickness in the range from 2 to 30 nm.

11. A method of depositing a film on a substrate, the method comprising:
depositing a Si-containing film on the substrate, wherein the Si-containing film is selected from the group consisting of SiN, SiO, SiON, SiC and SiCN; and
exposing the Si-containing film to a plasma comprising one or more dopant molecules comprising one or more of C, B, O, N and Ge.

12. The method of claim 11, wherein the Si-containing film is deposited via atomic layer deposition, plasma-enhanced atomic layer deposition, chemical vapor deposition, or spin-on dielectric deposition.

13. The method of claim 11, wherein the plasma comprises a saturated or unsaturated hydrocarbon.

14. The method of claim 11, wherein the plasma comprises diborane, hexamethyl borazine, a boron halide or a compound having the formula BHₓR₃₋ₓ, wherein each R is a C₁-C₆ alkyl group and x is 0, 1 or 2.

15. The method of claim 11, wherein the plasma comprises an alkyl amine.

16. The method of claim 11, wherein the plasma comprises germane or a germanium halide.

17. A method of depositing a C-doped SiN or SiON film on a substrate, the method comprising:
depositing SiN or SiON film on the substrate via atomic layer deposition or plasma-enhanced atomic layer deposition; and
doping the SiN or SiON film with C via a plasma implantation process to provide a doped film.

18. The method of claim 17, wherein doping the SiN or SiON film with C comprises exposing the SiN or SiON film to a plasma comprising a saturated or unsaturated hydrocarbon.

19. The method of claim 17, wherein the doped film has a relative carbon content in the range from 0.05 to 10 a.u.

20. The method of claim 17, wherein the doped film has a relative carbon content in the range from 0.1 to 1.0 a.u.
